(19) United States
(12) Patent Application Publication
(10) Pub. No.: US 2010/0267196 A1
(43) Pub. Date: Oct. 21, 2010

(54) HYBRID SYNTHESIS OF CORE/SHELL NANOCRYSTALS

(75) Inventors: Shimon Weiss, Los Angeles, CA (US); James M. Tsay, Los Angeles, CA (US); Malte Pflughoefft, Hamburg (DE)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 12/725,261

(22) Filed: Mar. 16, 2010

Related U.S. Application Data
(63) Continuation of application No. 10/573,254, filed on Mar. 23, 2006, now abandoned.
(60) Provisional application No. 60/505,461, filed on Sep. 24, 2003.

(51) Int. Cl. H01L 21/36; C09K 11/08; C09K 11/88; C09K 11/89

(52) U.S. Cl. 438/102; 252/301.4 R; 252/301.6 R; 977/700; 977/773; 257/E21.461

(57) ABSTRACT

Nanocrystals that include a core/shell structure in which the a core of semiconductor material is coated with an inorganic capping agent. The nanocrystals are made by initially providing nanocrystal precursors that include a solubility agent which renders the precursors soluble in an organic solvent. The nanocrystal precursors are then coated with the inorganic capping agent in the presence of an organic solvent.

### CROSS-REFERENCE TO RELATED APPLICATIONS

This application is a continuation of U.S. application Ser. No. 10/573,254, filed Mar. 23, 2006, which is a national phase of International Application No. PCT/US04/30995, filed Sep. 22, 2004, and claiming priority of U.S. Provisional Application No. 60/505,461, filed Sep. 24, 2003, the entire contents of which are incorporated herein by reference.

This invention was made with Government support under NIH Grant No. EB000312. The United States Government has certain rights in this invention.

### BACKGROUND OF THE INVENTION

1. Field of the Invention

The present invention relates generally to nanocrystals (NC's) that include a core of semiconductor material that is “capped” with an inorganic shell. More particularly, the present invention involves the discovery of a hybrid method for making such nanocrystals that combines the advantages of core synthesis in an aqueous solution with the advantages of inorganic shell synthesis or “capping” in organic solution.

2. Description of Related Art

The publications and other reference materials referred to herein to describe the background of the invention and to provide additional detail regarding its practice are hereby incorporated by reference. For convenience, the reference materials are numerically referenced and grouped in the appended bibliography.

Semiconductor NC's have size-tunable emissions due to the quantum size effect^{[1]} and exhibit a high resistance towards photobleaching. They typically range between 1-50 nm in diameter and are composed of inorganic materials with surfaces passivated by organic ligands. Most studied of these systems are CdSe NC's, which can emit in the whole visible range depending on their size. Recent advances in the synthesis of semiconductor NC's have allowed the emission of large wavelength ranges to be obtained. In particular, NC's emitting in the far red and near-infrared region have garnered much interest for in vivo biological imaging^{[2,3]} and the optoelectronics industry^{[4]}

Previously reported synthetic routes for preparing particles composed of CdTe, CdHgTe, and HgTe in water have shown much promise because of their possibilities for a large range of wavelength emissions in the near-IR tunable not only with size, but also with composition^{[4]}. These NC's, however, are not stable in biological environments because they are capped by organic ligands that do not function as a permanent means of complete passivation of the NC surface. Consequently, aggregation is likely to occur in such environments and non-radiative decay channels are always present, reducing quantum yields and more possibilities for quenching effects^{[5,6]}. Furthermore, these NCs are not exceptionally photostable, and thus far, there has been much more development of bioconjugation techniques on NC's synthesized in organic media (trioctylphosphine/trioctylphosphine oxide (TOP/TOPO)) than water-based NC's^{[7-15]}. For example, the only reported work for bioconjugation of water-based NC's is CdTe cores with silica shells which resulted in weakly fluorescent NC's^{[12}].

Near-IR-emitting NC's have also been synthesized in organic solvents such as TOP/TOPO. HgS NC's have been synthesized in organic solvents that can emit in a range between 500-800 nm at sizes between 1-5 nm^{[16]}. Their limited wavelength range (especially in the near-IR) and small fluorescence quantum yields (5 to 6% with passivation of Cd or Zn) as well as their large size distribution (20-30%) limit their applications. Furthermore, incorporating mercury in organic solvents is much more difficult than cadmium because suitable mercury precursors are extremely toxic and their reactivity is harder to control at high temperatures (>100° C.)^{[17]}. Therefore, longer wavelength-emitting HgSe, HgTe, and CdHgTe NC's of appreciable quality are very difficult to synthesize in organic solvents.

More promisingly, InAs/CdSe, InAs/ZnSe, InAs/InP, and InAs/ZnS core shell NC's have been synthesized which exhibit improved stability to oxidation and photobleaching^{[18]}. However, these NC's can only emit between 800-1400 nm, tunable only with their size. Furthermore, quantum yields of these NC's are limited to at most 20%. Recently, the synthesis of alloy CdSeTe NC's in TOP/TOPO/amines has been reported^{[19]}. These NC's exhibit high quantum yields (30-60%), narrow emission, and near-IR fluorescence. However, their wavelength range is limited to at most 850 nm emission, corresponding to a very large NC size (8.6 nm). Also, it has yet to be reported that these alloy NC cores can exhibit a high degree of resistance to photobleaching and oxidation. In order to be suitable for many in vivo biological applications, NCs must be able to be bioconjugated, emit strongly in the near-IR, exhibit resistance to photobleaching and oxidation, and must be kept at a small (˜5 nm or less) size.

In order to obtain all of these properties for semiconducting NC's it is useful to combine the strengths of different synthesis routes. The ability to easily incorporate mercury into CdTe NC's synthesized in water is greatly advantageous because of the possibility to keep NC's the same size with a large wavelength emission range controlled by composition. In addition, the band gap structure is still a type I with a lower band gap core material and a larger band gap shell material, which do not lead to charge separation and long fluorescence life time^{[19,20]}.

There is, however, little work done on the synthesis of thin, highly crystalline, high band-gap shells in water^{[4,21,22]}. It has been reported that CdS shells can be grown over HgTe in water, which allows greater stability to temperature^{[21]}. However these shells increase the size of the NCs (>2 nm shell) and do not increase their quantum yield appreciably. Recent work by Gaponik, et. al. has shown that CdTe synthesized in water can be transferred to organic solvents through efficient phase transfer^{[23]}. This method allows the utilization of the positive aspects of the water-based synthesis routes (easier to dope, highly reproducible, controllable, much less expensive, less toxic, and more environmentally friendly) while allowing for the potential to use positive aspects of NC's synthesized in organics (more mature developments of higher band gap shells and bioconjugation). The purpose of their work was to allow these NC's to be compatible with common organic solvents, monomers, and polymers, essential for optoelectronics applications.

In order to provide increased oxidation resistance and photostability for use in optoelectronics and biological applications, it is imperative to passivate the surface of CdTe, CdHgTe, and HgTe with higher band gap shells. Previous reports have shown that robust, photostable, and highly luminescent NCs can be obtained by growing higher band gap shells around cores to make structures such as CdSe/CdS and CdSe/ZnS^{[24-26]}.

### SUMMARY OF THE INVENTION

In accordance with the present invention, a method is provided for the synthesis of highly luminescent CdTe/ZnS, CdHgTe/ZnS, CdHgTe/CdSZnS, HgTeCdTe/CdSZnS, and HgTe/CdSZnS core/shell semiconductor nanocrystals (NC's). The invention is based in part on a mixture of two synthesis routes that leads to novel NC compositions using the large variety of core materials available through the water based synthesis, while maintaining the high quality of particles that are usually derived by high temperature (organic solvent) methods. With the hybrid approach of the present invention, NC's can be made that emit at a very extensive wavelength range (from 500-2000 nm), exhibit high resistance to oxidation and photobleaching, high quantum yields (greater than 50%) and can be rendered water-soluble and biologically active with established methods (polymer coating, ligand exchange, lipid vesicles or micelles, peptides). Because of these qualities, the NC's that are made in accordance with the present invention can be used as highly effective probes for numerous applications. These include multicolor single-molecule fluorescence cellular imaging with greatly reduced background, in vivo biological imaging with increased tissue penetration of excitation and emission light, materials for optoelectronic devices and possibly even as therapeutic reagents.

The present invention is based in part on our discovery that the ability to transfer water-based cores to organic solvents allows one to easily grow shells around these cores to form NC's of compositions that were previously unattainable. The various ways developed to bioconjugate CdSe/ZnS in TOP/TOPO can be applied to these novel NC's because they have the same outer environment. In particular, it has been shown that these NC's can be rendered water-soluble with peptide coatings^{[27]}.

The present invention provides a method for making a nanocrystal that includes a core which has a surface that is coated with an inorganic capping agent. The method includes the initial step of providing a nanocrystal precursor that comprises a core having a surface that includes a sufficient amount of a solubility agent to render said nanocrystal precursor soluble in an organic solvent. The core is then coated with a sufficient amount of an inorganic capping agent to form the final nanocrystal. As a feature of the present invention, the nanocrystal precursor is initially formed in aqueous media and is water-soluble. The nanocrystal precursor is rendered hydrophobic and soluble in organic solvents by treating it with a solubility agent (e.g. dodecanthiol) in the presence of a surfactant (e.g. acetone) as is known in the art. The resulting hydrophobic nanocrystal precursor is then coated or “capped” with an inorganic capping agent in the presence of an organic solvent.

By using the hybrid approach to the synthesis of core shell NC's in accordance with the present invention, it is possible to synthesize a series of NC's that emit in an extensive wavelength range (500-2000 nm) and that are tunable with composition instead of size, with high quantum yield (over 50%) and high resistance to photobleaching and oxidation. This invention allows extremely robust IR-emitting NC's to be processed so that they are applicable for cellular imaging with reduced background, in vivo imaging with increased sensitivity, and employed as emitters for opto-electronics devices.

The above discussed and many other features and attendant advantages of the present invention will become better understood by reference to the detailed description when taken in conjunction with the accompanying drawings.

### BRIEF DESCRIPTION OF THE DRAWINGS

FIG. 1 is a graph showing the absorption and emission of CdTe nanocrystal cores before phase transfer (curves labeled A) and after phase transfer and shell growth in accordance with the present invention (curves labeled B).

FIG. 2 is a graph showing the absorption and emission of CdHgTe nanocrystal cores before phase transfer (curves labeled A) and after phase transfer and shell growth in accordance with the present invention (curves labeled B).

FIG. 3 is a graph showing fluorescence correlation spectroscopy. (FCS) data and fit for CdHgTe nanocrystals for different excitation energies.

FIG. 4 is a graph showing FCS data and fit for CdHgTe/ZnS nanocrystals made in accordance with the present invention for different excitation energies in butanol.

### DETAILED DESCRIPTION OF THE INVENTION

The present invention involves a method for making core/shell nanocrystals where the core is initially made in aqueous solution according to known procedures that include capping or passivating the surfaces of the cores with a stabilizing agent, such as short chain thiol groups. The water soluble capped-cores are then treated with a sufficient amount of a solubility agent, according to known procedures, to form a nanocrystal precursor that includes a core having a surface that includes a sufficient amount of the solubility agent to render the nanocrystal precursor soluble in organic solvents. The nanocrystal precursor is then dissolved in an organic solvent and treated with a sufficient amount of an inorganic capping agent, in accordance with known capping methods in organic solvents, to form the final core/shell nanocrystal.

The cores of the nanocrystal precuror may include any of the semiconductor materials that are amenable to synthesis by known water-based core formation methods. Exemplary cores include CdTe, CdHgTe, HgTe and mixtures thereof. Other cores are possible provided that they are synthesized in aqueous media according to known procedures for making nanocrystal cores that are suitable for use in fluorescence spectroscopy. The stabilizing agent or organic capping agent that is applied to the initially formed water-soluble core can be any of the known organic capping (stabilizing) agents. Short chain thiol stabilizing agents are preferred. Exemplary stabilizing agents include: 1-thioglycerol, 2-mercaptoethanol, 2-mercaptoacetic acid and 2-aminoethanediol. The procedures for making water-soluble nanocrystals that are capped with an organic capping agent are known in the art and are described in detail in the literature. For example, see Refs. 4-15.

In order to be suitable as a nanocrystal precursor in accordance with the present invention, the organic-capped, water-soluble nanocrystal core must be rendered soluble in organic solvents, such as toluene, benzene, chloroform and the like. This is accomplished by treating the organic-capped, water-soluble core with a solubility, agent in accordance with known phase transfer methods^{[23]}. The phase transfer basically involves exposing an aqueous solution of the water-soluble nanocrystal to a suitable solubility agent, such as dodecanethiol or other long chain thiol. Long chain aliphatic thiols have been widely used in the past to indirectly extract metals and semiconductor NC's into organic solvents^{[23]}. As is also known, a surfactant, such as acetone, must be included with the dodecanthiol or other solubility agent in order to provide for the direct transfer of the nanocrystal from the aqueous solution into the organic solution. Surfactants other than acetone may be used provided that they are soluble in both the aqueous phase and the organic phase. The phase transfer process occurs due to the replacement of short chain organic stabilizing molecules on the core surface with the longer chain aliphatic thiols which render the nanocrystal core soluble in organic solvents.

Once the nanocrystal precursor has been formed, it is then coated with an inorganic capping agent (in the presence of an organic solvent) to form the core/shell nanocrystal. Suitable inorganic capping agents include any of the known capping agents that are applied in organic solvent using known capping methods. For example see Ref. 24. Exemplary inorganic capping agents include CdS, ZnS and mixtures thereof. After inorganic capping, the nanocrystal (core coated with the inorganic capping agent) can then be further treated, if desired, in accordance with known procedures to render the nanocrystals suitable for intended uses. For example the nanocrystals may be coated with peptide (See PCT US03/14401) or bioconjugated using micelles^{[14]} or ligand exchange^{[3]}.

Examples of Practice are as Follows:

The following materials were used in the examples of the invention that are set forth below: Mercaptoacetic acid (C₂H₄O₂S, 98%) and 2-aminoethanethiol hydrochloride (C₂H₇NS—HCl, 98%) were purchased from Acros Organics. Al₂Te₃ (lumps) were purchased form CERAC Inc., WI. Milli-Q water (Millipore water, 18.2 MΩ) was used as solvent in the water-based synthesis. Dimethyl Cadmium (Cd(CH₃)₂, 97%) and tri-n-butylphosphine (TBP, 99%) were purchased from Strem. Cd(CH₃)₂ was vacuum distilled and stored at −35° C. in an Ar-filled glove box. 1-dodecanethiol (C₁₂H₂₆S), diethylzinc (C₄H₁₀Zn or ZnEt₂, 1.0 M solution in heptane), trioctylphosphine (TOP, Tech grade), Trioctylphosphineoxide (TOPO, 99%), hexamethyldisilithiane (C₆H₁₈Si₂S or TMS2S) were purchased from Aldrich. Cd(ClO₄)₂.6(H₂O), Hg((ClO₄)₂.3(H₂O), tetradecylphosphonic acid (TDPA, 99%) and trioctylphosphine oxide (TOPO, Tech grade) were purchased from Alfa Aesar.

Synthesis of CdTe Cores:

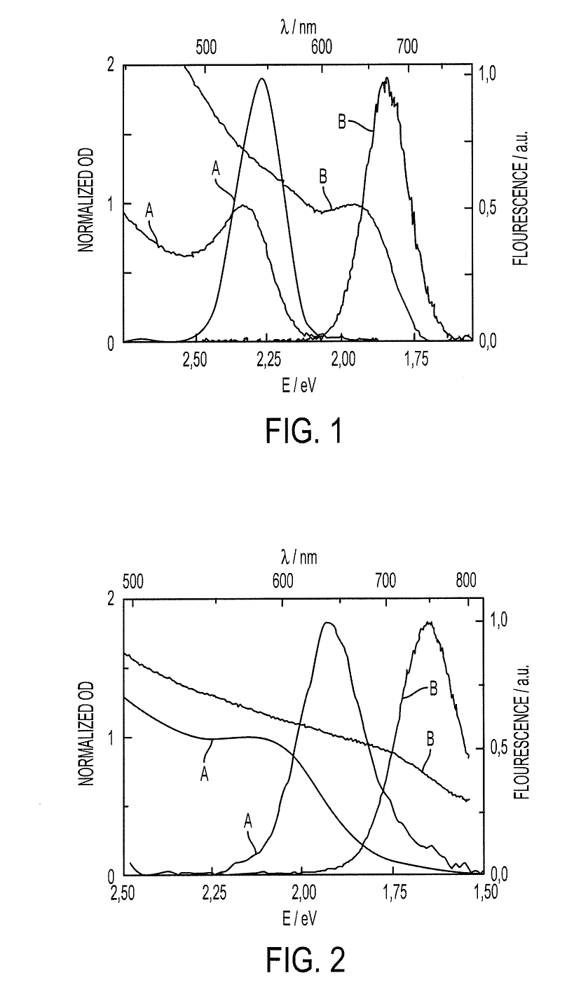

Synthesis of CdTe cores was based on a procedures developed by Rogach, et. al.^{[28,29]}. Cd(ClO₄)₂.6(H₂O) (0.99 g), Millipore water (125 mL), and mercaptoacetic acid (0.4 mL) or 2-aminoethanethiol (0.44 g) were added to a 3-neck 250 mL round-bottomed flask. For mercaptoacetic acid-stabilized NCs, the pH was adjusted to 11.2. This mixture was degassed and allowed to stir at room temperature. Under nitrogen flow H₂Te gas was flowed into a solution of 0.05M NaOH via the dropwise addition of 0.05M H₂SO₄ (7.5 mL) into a flask containing Al₂Te₃ (0.2 g, 0.46 mmol), generating NaHTe in the solution. This solution containing NaHTe (22 mL) was quickly injected in the solution containing the cadmium precursor, and the mixture was stirred for 30 min. The solution was then refluxed at 100° C. for normally 1 hour (also between 15 min and 1 day). Typical absorption and emission spectra are shown in FIG. 1 (see curves labeled A).

Synthesis of CdHgTe HgTe Cores:

For small CdHgTe NCs emitting in the visible range, Hg((ClO₄)₂.3(H₂O)) (0-2.5% molar ratio) dispersed in ultrapure water was added to the reaction flask in the CdTe reaction above at different times before the reflux step. For CdHgTe and HgTe cores emitting in the near-IR, procedures used in work by A. L. Rogach, et. al.^{[4]} were used. Typical absorption and emission spectra are shown FIG. 2 (see curves labeled A).

Phase Transfer:

The phase transfer procedure is a slight modification of the one reported by Gaponik, et. al.^{[23]}. It has been modified to increase both the optical properties of the cores and to yield a suitable amount of cores for the shell synthesis. Typically, an aliquot of CdTe or CdHgTe core solution (stabilized by 2-aminoethanethiol) was mixed with another aliquot of dodecanethiol (at a 1:1 ratio). An amount of acetone was added to the mixture (1:1 to 2:1 ratio) as an interfacial solvent, and the solution was stirred vigorously and heated to 60° C., when necessary, until complete phase transfer. The organic layer containing the NC's was extracted and diluted (1:1) with toluene. The mixture was then refluxed at 120° C. for 1 hour to repair surface traps and increase the photoluminescence intensity of the NC's. This mixture was cooled to room temperature and precipitated with methanol.

Shell Synthesis:

The shell synthesis (inorganic capping) on NC cores is a modification of the one done by Hines, et. al.^{[24]}. 5-40 mg of precipitated dodecanethiol-capped (organic capped) cores were re-dispersed in 0.5 mL of chloroform. A solution containing TBP (8.26 g), diethylzinc (1.26 g), hexamethyldisilithiane (0.304 g), and optionally dimethyl cadmium, was prepared in a glove box. A solution of technical grade TOPO (4 g) was heated to 100° C. and purged for 30 minutes under vacuum. This was repeated twice for 5 minute intervals. TOP or TBP (0.5 mL) is injected into the TOPO solution. The core solution is also injected into the solution and purged in order to evaporate chloroform. The reaction flask is filled with nitrogen and heated to 160° C. with TBP and 170° C. or higher with TOP. The shell solution is injected at approximately 0.1 mL/min. Typically, a red shift of approximately 130 nm is observed between the original CdTe or CdHgTe cores and the core shell NC's. The desired red-shift of the wavelength of emission is dependent on reaction time, and is controlled most often by varying, amount of cores injected in the solution in order to keep dropping rates of shell precursors the same. After the shell, precursor addition was completed the reaction flask was left at 160° C. for 10 min, and then 90° C. for 30 min. The reaction was cooled to 40° C. and 2-3 mL of butanol (99.99%) were added.

Alternatively, solvent mixtures can be modified with pure TOPO as the main component. For example, adding different amounts of tetradecylphosphonic acid (TDPA) results in controllable red-shifts as well as quantum yields. The rest of the reaction procedure remains the same. Typical spectra are shown in comparison to the core material in FIG. 1 for CdTe (see curves labeled B) and in FIG. 2 for CdHgTe (also see curves labeled B). A red shift between the starting material and the final core shell structure can be seen, as well as a constant full width at half maximum.

The core/shell NC's described in this invention may be excited with light of any wavelength that has greater energy than their band gap energy. Light is then emitted from these NC's of wavelength corresponding to the band gap energy. For biological applications, these NC's may be rendered water-soluble and bioactive. All bioconjugation schemes currently available for CdSe/ZnS NC's^{[7-11, 13-15]} may be used with the NC's described in this invention. The NC's described in this invention have been rendered water soluble using peptide coating. This coating allows these IR-emitting NC's to be linked to nucleic acids, peptides, proteins, and antibodies.

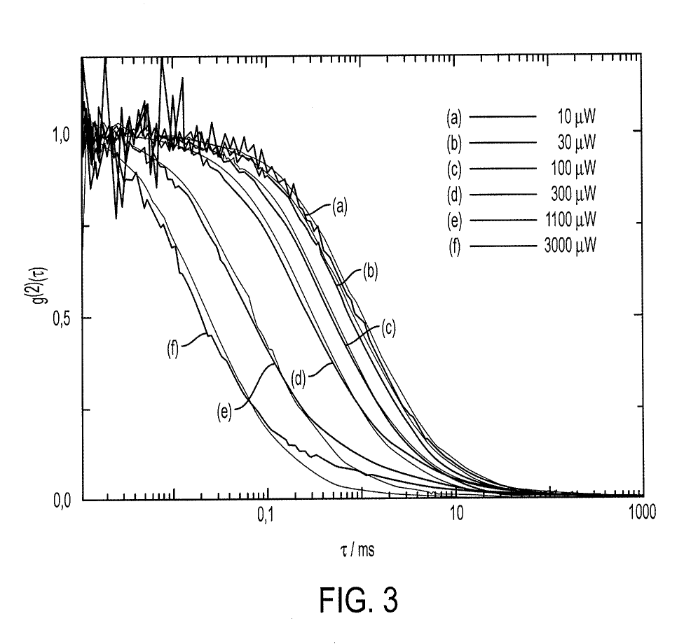

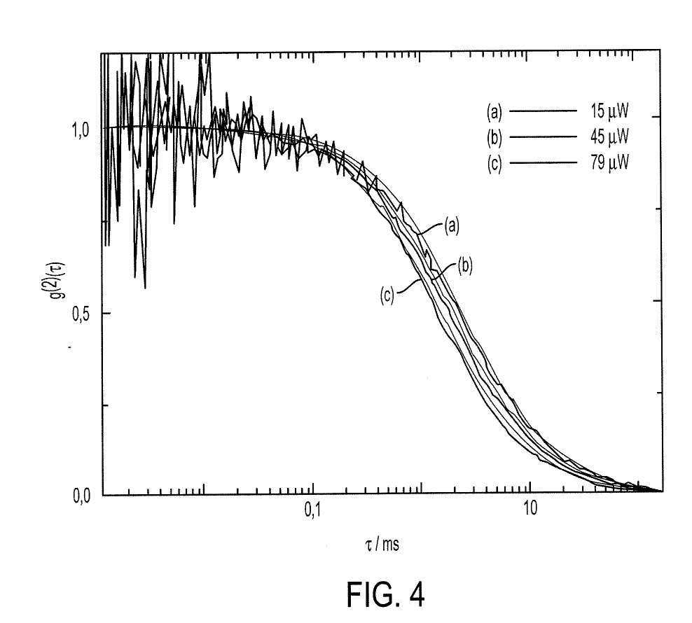

The NC's made in accordance with the present invention are exceptionally stable to photo-bleaching. For example, even upon hours of extensive exposure to continuous UV lamp or laser radiation, little photo-bleaching occurs. Fluorescence correlation spectroscopy (FCS) was done on core and core/shell samples, to determine size (through diffusion), brightness per particle and bleaching behavior. In the FCS data, it can be seen that photobleaching effects are much more present in the water-based cores (See FIG. 3) before they are overcoated (capped) by a higher-band gap shell (See FIG. 4). In FIG. 3, a power dependent series of FCS measurements of CdHgTe cores is shown. By increasing the power, bleaching of the particles can, be observed. In comparison, the CdTe/ZnS core/shell samples do not show bleaching. In FIG. 4, a power dependent series of FCS measurements of CdHgTe/ZnS is shown. These can be fitted very well through a simple 2D diffusion model, which is not the case for high powers in FIG. 3. Since FCS is a measure of colloidal properties of these NC's in solution, they more appropriately describe optical properties of the NC's in a biologically relevant environment than surface measurements. In addition, FCS demonstrates that the NC's in accordance with the present invention can be used in single molecule methods.

Furthermore, the NC's made in accordance with the present invention exhibit exceptionally high quantum yields, typically in the range between 40-60%. Because of their stability against photo-bleaching and oxidation, the NC's described in this invention can be used to extend the amount of colors for multicolor co-localization in single molecule imaging. This, however, requires narrow emission bands and these NC's have rather large full width half maximum (FWHM) (>140 meV) in the near infrared range. Size-selective precipitation (especially for pure CdTe and HgTe) can help narrow size distributions, and thus bandwidth of emissions. Their broad emission characteristics are, however, ideal for the optoelectronics industry. Because of their solubility with organic solvents, the NC's made using the hybrid approach of the present invention are even more applicable for this industry.

NC's made in accordance with the present invention also have many potential biological applications, in vitro, ex vivo and especially in vivo. Because of the auto-fluorescence background in living systems (usually in the shorter wavelength visible regime), it is increasingly difficult to resolve the NC's. In order to reduce the background in cellular imaging, longer wavelength emission of these NC's may be utilized. It has yet to be reported that very photostable near-IR emitting NC's have been bioconjugated and specifically targeted to cells. Because most visible light does not penetrate well within living tissue, it is difficult to probe in vivo environments with high sensitivity. Because the present NC's can emit in the “open window” range between 650-900 nm and can be excited at any energy below its band gap (with any radiation shorter then the emission wavelength), highly effective in vivo imaging can take place with increased penetration.

Having thus described exemplary embodiments of the present invention, it should be noted by those skilled in the art that the within disclosures are exemplary only and that various other alternatives, adaptations and modifications may be made within the scope of the present invention. Accordingly, the present invention is not limited to the above preferred embodiments and examples, but is only limited by the following claims.

### BIBLIOGRAPHY

[1] A. P. Alivisatos, Science 1996, 271, 933.
[2] M. Bruchez Jr., M. Moronne, P. Gin, S. Weiss, A. P. Alivisatos, Science 1998, 281, 2013.
[3] W. C. W. Chan, S, Nie, Science 1998, 281, 2016.
[4] A. L. Rogach, M. T. Harrison, S. V. Kershaw, A. Kornowski, M. G. Burt, A. Eychmüller, H. Weller, phys. stat. sol (b) 2001, 224, 153.
[5] J. E. Bowen Katari, V. L. Colvin, A. P. Alivisatos, J. Phys. Chem. 1994, 98, 4109.
[6] J. Aldana, Y. A. Wang, X. Peng, J. Am. Chem. Soc. 2001, 123, 8844.
[7] N. N. Mamedova, N. A. Kotov, A. L. Rogach, J. Studer, Nano Lett. 2001, 1, 281.
[8] S. Pathak, S.-K. Choi, N. Arnheim, M. E. Thompson, J. Am. Chem. Soc. 2001, 123, 4103
[9] W. J. Parak, D. Gerion, D. Zanchet, A. S. Woerz, T. Pellegrino, C. Micheel, S. C. Williams, M. Seitz, R. E. Bruehl, Z. Bryant, C. Bustamante, C. R. Bertozzi, A. P. Alivisatos; Chem. Mater. 2002, 14, 2113.
[10] M. E. Akerman, W. C. W. Chan, P. Laakkonen, S. N. Bhatia, E. Ruoslahti, Proc. Natl. Acad. Sci. 2002, 99, 12617.
[11] G. P. Mitchell, C. A. Mirkin, R. L. Letsinger, J. Am. Chem. Soc. 1999, 121, 8122.
[12] A. Schroedter, H. Weller, R. Eritja, W. E. Ford, J. M. Wessels, Nano Lett. 2002, 2, 1363
[13] E. R. Goldman, E. D. Balighian, H. Mattoussi, M. K. Kuno, J. M. Mauro, P. T. Tran, G. P. Anderson, J. Am. Chem. Soc. 2002, 124, 6378.
[14] B. Dubertret, P. Skourides, D. J. Norris, V. Noireaux, A. H. Brivanlou, A. Libchaber, Science 2002, 298, 1759.
[15] S. J. Rosenthal, I. Tomlinson, A. M. Adkins, S. Schroeter, S. Adams, L. Swafford, J. McBride, Y. Wang, L. J. DeFelice, R. D. Blakely, J. Am. Chem. Soc. 2002, 124, 4586.
[16] K. A. Higginson, M. Kuno, J. Bonevich, S. B. Qadri, M. Yousuf, H. Mattoussi, J. Phys. Chem. B 2002, 106, 9982.
[17] M. Kuno, K. A. Higginson, S. B. Qadri, M. Yousuf, S. H. Lee, B. L. Davis, H. Mattoussi, J. Phys. Chem. B 2003, 107, 5758.
[18] Y. Cao, U. Banin, J. Am. Chem. Soc. 2000, 122, 9692.
[19] R. Bailey, S, Nie, J. Am. Chem. Soc. 2003, 125, 7100.
[20] S. Kim, B. Fisher, H.-J. Eisler, M. Bawendi, J. Am. Chem. Soc. 2003, ASAP.
[21] M. T. Harrison, S. V. Kershaw, A. L. Rogach, A. Kornowski, A. Eychmüller, H. Weller, Adv. Mater. 2000, 12, 123.
[22] S. V. Kershaw, M. G. Burt, M. T. Harrison, A. L. Rogach, H. Weller, A. Eychmüller, Appl. Phys. Lett. 1999, 75, 1694.
[23] N. Gaponik, D. V. Talapin, A. L. Rogach, A. Eychmüller, H. Weller, Nano Lett. 2002, 2, 803.
[24] M. A. Hines, P. Guyet-Sionnest, J. Phys. Chem. 1996, 100, 468.
[25] B. O. Dabbousi, J. Rodriguez-Viejo, F. V. Mikulec, J. R. Heine, H. Mattoussi, R. Ober, K. F. Jensen, M. G. Bawendi, J. Phys. Chem. B 1997, 101, 9463.
[26] X. Peng, M. C. Schlamp, A. Kadavanich, A. P. Alivisatos, J. Am. Chem. Soc. 1997, 119, 7019.
[27] F. Pinaud, S. Weiss, in U.S. Provisional Patent Ser. No. 60/378,720, UCLA, USA, 2002.
[28] N. Gaponik, D. V. Talapin, A. L. Rogach, K. Hoppe, E. V. Shevchenko, A. Kornowski, A. Eychmüller, H. Weller, J Phys. Chem. B 2002, 106, 7177.
[29] A. L. Rogach, L. Katsikas, A. Kornowski, D. Su, A. Eychmüller, H. Weller, Ber. Bunsenges. Phys. Chem. 1996, 100, 1772.

We claim:

1. A method for making a nanocrystal that includes a core which has a surface that is coated with an inorganic capping agent, said method comprising the steps of:
providing a nanocrystal precursor that comprises a core having a surface that includes a sufficient amount of a solubility agent to render said nanocrystal precursor soluble in an organic solvent; and
coating the surface of said nanocrystal precursor with a sufficient amount of an inorganic capping agent to form said nanocrystal, wherein said coating of the surface of said nanocrystal precursor with said inorganic capping agent takes place in the presence of an organic solvent.

2. A method for making a nanocrystal according to claim 1 wherein the core of said nanocrystal precursor comprises a semiconductor material selected from the group consisting of CdTe, CdHgTe, HgTe and mixtures thereof.

3. A method for making a nanocrystal according to claim 1 wherein said inorganic capping agent is selected from the group consisting of CdS, ZnS and mixtures thereof.

4. A method for making a nanocrystal according to claim 2 wherein said inorganic capping agent is selected from the group consisting of CdS, ZnS and mixtures thereof.

5. A method for making a nanocrystal according to claim 1 wherein said solubility agent is a long chain aliphatic thiol.

6. A method for making a nanocrystal according to claim 4 wherein said semiconductor material is. CdTe, CdHgTe or HgTe and said capping agent is ZnS.

7. A method for making a nanocrystal according to claim 1 wherein said nanocrystal precursor is made by a method comprising the steps of:
providing a water soluble nanocrystal that comprises a core and a surface wherein said surface comprises stabilizing molecules; and
treating said water soluble nanocrystal with a sufficient amount of said solubility agent in the presence of a surfactant to replace at least a portion of said stabilizing molecules with said solubility agent to thereby provide said nanocrystal precursor that is soluble in an organic solvent.

8. A method for making a nanocrystal according to claim 7 wherein said stabilizing molecules comprise short chain thiols.

9. A method for making a nanocrystal according to claim 8 wherein said solubility agent comprises a long chain thiol.

10. A method for making a nanocrystal according to claim 9 wherein said solubility agent comprises dodecanethiol.

11. A method for making a nanocrystal according to claim 7 wherein said surfactant comprises acetone.

12. In a method for making a nanocrystal where a core is first formed and then coated with an inorganic capping agent, the formation of said core and the coating of said core with said inorganic capping agent being both carried out in the presence of an organic solvent, the improvement comprising:
forming said core in an aqueous solvent instead of an organic solvent to thereby provide a water soluble core; and
treating said water soluble core with a sufficient amount of a solubility agent in the presence of a surfactant so that said water soluble core is converted into a core that is soluble in organic solvents whereby said core can then be coated with said inorganic capping agent in the presence of said organic solvent.

13. An improved method for making a nanocrystal according to claim 12 wherein said core that is formed in aqueous solvent comprises a semiconductor material selected from the group consisting of CdTe, CdHgTe, HgTe and mixtures thereof.

14. An improved method for making a nanocrystal according to claim 12 wherein said inorganic capping agent is selected from the group consisting of CdS, ZnS and mixtures thereof.

15. An improved method for making a nanocrystal according to claim 13 wherein said inorganic capping agent is selected from the group consisting of CdS, ZnS and mixtures thereof.

16. An improved method for making a nanocrystal according to claim 12 wherein said solubility agent is a long chain aliphatic thiol.

17. An improved method for making a nanocrystal according to claim 16 wherein said solubility agent is dodecanethiol.

18. An improved method for making a nanocrystal according to claim 17 wherein said semiconductor materis is CdTe or CdHgTe and said capping agent is ZnS.

19. An improved method for making a nanocrystal according to claim 12 wherein said surfactant comprises acetone.

20. An improved method for making a nanocrystal according to claim 12 wherein said water soluble core has a surface and wherein said surface comprises stabilizing molecules.

21. An improved method for making a nanocrystal according to claim 20 wherein said stabilizing molecules comprise short chain thiols.

22. A composition of matter comprising a nanocrystal that includes a core which has a surface that is coated with an inorganic capping agent, said nanocrystal being made according to the method set forth in claim 1.

23. A composition of matter comprising a nanocrystal that includes a core which has a surface that is coated with an inorganic capping agent, said nanocrystal being made according to the method set forth in claim 2.

24. A composition of matter comprising a nanocrystal that includes a core which has a surface that is coated with an inorganic capping agent, said nanocrystal being made according to the method set forth in claim 3.

25. A composition of matter comprising a nanocrystal that includes a core which has a surface that is coated with an inorganic capping agent, said nanocrystal being made according to the method set forth in claim 4.

26. A composition of matter comprising a nanocrystal that includes a core which has a surface that is coated with an inorganic capping agent, said nanocrystal being made according to the method set forth in claim 5.

27. A composition of matter comprising a nanocrystal that includes a core which has a surface that is coated with an inorganic capping agent, said nanocrystal being made according to the method set forth in claim 6.

28. A composition of matter comprising a nanocrystal that includes a core which has a surface that is coated with an inorganic capping agent, said nanocrystal being made according to the method set forth in claim 7.

29. A composition of matter comprising a nanocrystal that includes a core which has a surface that is coated with an inorganic capping agent, said nanocrystal being made according to the method set forth in claim 8.

30. A composition of matter comprising a nanocrystal that includes a core which has a surface that is coated with an inorganic capping agent, said nanocrystal being made according to the method set forth in claim 9.

31. A composition of matter comprising a nanocrystal that includes a core which has a surface that is coated with an inorganic capping agent, said nanocrystal being made according to the method set forth in claim 10.

32. A composition of matter comprising a nanocrystal that includes a core which has a surface that is coated with an inorganic capping agent, said nanocrystal being made according to the method set forth in claim 11.

33. A composition of matter according to claim 25 wherein said core consists essentially of CdTe.

34. A composition of matter according to claim 25 wherein said core consists essentially of CdHgTe.

35. A composition of matter according to claim 25 wherein said core consists essentially of HgTe.
